(19) United States
(12) Patent Application Publication
(10) Pub. No.: US 2010/0307581 A1
(43) Pub. Date: Dec. 9, 2010

(54) LARGE AREA DYE CELLS, AND METHODS OF PRODUCTION THEREOF

(75) Inventors: Barry Breen, Jerusalem (IL); Ilya Yakupov, Rehovot (IL); Jonathan Goldstein, Jerusalem (IL)

Correspondence Address: Marc Van Dyke, 123 N.W. 13th Street, Suite 221, Boca Raton, FL, 33432-1619, US

(73) Assignee: 3GSOLAR LTD., Jerusalem (IL)

(21) Appl. No.: 12/744,914

(22) PCT Filed: Nov. 26, 2008
(86) PCT No.: PCT/IL08/01550

§ 371 Date: May 26, 2010

Related U.S. Application Data
(60) Provisional application No. 60/990,307, filed on Nov. 27, 2007.

(51) Int. Cl. H01L 31/0216; H01L 31/02; H01L 31/18

(52) U.S. Cl. 136/256; 438/64; 257/E31.117

(57) ABSTRACT

A photovoltaic cell for converting a light source into electricity, including an at least partially transparent cell wall having an intenor surface, an electrolyte, disposed within the cell wall, containing a redox species, and at least partially transparent conductive coating disposed on the intenor surface, an anode adapted to convert photons to electrons, including a porous titania film disposed on the conductive coating and adapted to contact the redox species, the film having a plurality of continuous areas separated by gaps disposed along a length of the film, and a dye, absorbed on a surface of the film, a cathode disposed opposite the anode, to effect electrolytic communication, via the electrolyte, with the porous film, and at least two conductor structures, disposed within the gaps, electrically connected to the anode and to the conductive coating, and abutting the film

This application draws priority from U.S. Provisional Patent Application Ser. No. 60/990,307, filed Nov. 27, 2007.

### FIELD AND BACKGROUND OF THE INVENTION

The present invention relates to photovoltaic cells, also known as solar cells, for producing electricity from sunlight, and more particularly, to monolithic solar cells of the dye-sensitized type, and to methods for producing such cells.

Dye-sensitized photovoltaic cells for producing electricity from sunlight have been disclosed by U.S. Pat. No. 5,350,644 to Graetzel, et al. U.S. Pat. No. 5,350,644 teaches a photovoltaic cell having a light-transmitting, electrically-conductive layer deposited on a glass plate or a transparent polymer sheet to which a series of titanium dioxide layers have been applied, in which at least the last titanium dioxide layer is doped with a metal ion that is selected from a divalent or trivalent metal.

Following U.S. Pat. No. 5,350,644, U.S. Pat. No. 6,069,313 to Kay teaches a plurality of series-connected cell elements arranged as separate, parallel, narrow elongated strips on a common transparent substrate. Each element includes a light facing anode containing nanocrystalline titania, a carbon-based counter-electrode (cathode), and an intermediate electrically insulating porous layer, based on alumina, silica, titania or zirconia, separating the anode from the cathode. The pores of the intermediate layer are at least partially filled with a liquid phase, ion-transferring electrolyte, following coating of the nanocrystalline titania with a light-sensitive dye. A current collecting layer of a tin oxide based transparent, electrically-conducting material is situated between the transparent substrate and the anode. The anode and cathode of a given cell provide a direct-current voltage when the anode is exposed to light, such that series assemblies of cells may readily be built up. The cathode of each succeeding element is connected with the intermediate conducting layer of the preceding anode element, over a gap separating the respective intermediate layers of these two elements. The series of cells is then sealed using an organic polymer, ensuring in particular that each individual strip cell is sealed from its neighbor cell, and this assembly is referred to as a monolithic assembly of cells.

Generally, dye cells of the above-cited prior art disclosures are much closer conceptually to battery cells than to conventional photovoltaic cells, since the charge generators are separated by an electrolyte and are not in direct contact. These cells have two electrodes separated by an electrolyte, with one electrode (the photoelectrode or photoanode) facing the sun or light source. Each electrode is supported on its own current collector, usually a sheet of conducting glass, which is glass coated on one side with a thin (˜0.5 micrometer) transparent layer, usually based on electrically-conductive tin oxide. The conducting glass sheets act as transparent walls of the dye cell.

A transparent polymer may be used in place of glass to support the tin oxide. The photo-electrode or photoanode includes a transparent porous layer about 4-20 micrometers thick (in contact with the tin oxide layer) based on titania, having a nanocrystalline characteristic particle size of 9-50 nm, applied by baking onto the conductive glass or transparent polymer, and impregnated with a special dye. The baked-on titania layer is applied in dispersion form by any of various methods: doctor-blading, rolling, spraying, painting, electrophoresis, gravure printing, slit coating, screen printing or printing. The baking step giving highest cell performance is usually at least 450° C., requiring the use of conducting glass rather than plastic for supporting the titania layer. Other processing procedures for the titania layer are feasible, such as reduced temperature baking, or pressing, usually with some sacrifice in efficiency. It is important to note that the titania is principally in contact with the tin oxide. Presence of other conductors (such as many metals, carbon and the like, even if chemically inert to the electrolyte) on the photoanode can greatly increase recombination of charge carriers and provide a serious efficiency loss in the cell. Very few materials (amongst them tin oxide and titanium metal) are applicable for inclusion as conductors as part of the photoanode, due to the rigorous criteria for the conductor chosen, including chemical inertness to the electrolyte, electrical resistivity below 10⁻⁴ ohm cm, and characteristically no tendency or practically no tendency for recombination.

For cells that are partially transparent, the other electrode (the counter-electrode) includes a thin layer of catalyst (usually containing a few micrograms of platinum per sq. cm) on its respective sheet of tin oxide coated conductive glass or transparent plastic. If cell transparency is not required, the counter-electrode can be opaque, for example, based on carbon or graphite advantageously catalyzed with trace platinum or other active electrocatalyst. The electrolyte in the cell is usually an organic solvent with a dissolved redox species. The electrolyte is typically acetonitrile or a higher molecular weight, reduced volatility nitrile, with the redox species in classical dye cells being dissolved iodine and potassium iodide—essentially potassium tri-iodide. Other solvents and phases, for example ionic liquids with zero vapor pressure, and different redox species, may be used, however.

U.S. Pat. No. 5,350,644 to Graetzel, et al., discloses various dye cell chemistries, especially different dyes based on ruthenium complexes. Photons falling on the photoelectrode excite the dye (creating activated oxidized dye molecules), causing electrons to enter the conduction band of the titania and to flow (via an outer circuit having a load) to the counter-electrode. There, the electrons reduce tri-iodide to iodide in the electrolyte, and the iodide is oxidized by the activated dye at the photoanode back to tri-iodide, leaving behind a deactivated dye molecule ready for the next photon. It is disclosed that such dye cells can attain a solar-to-electric conversion efficiency of 10% and over 11% has been achieved in small area (typically 0.2 mm square) champion research cells.

The cells of U.S. Pat. No. 5,350,644 to Graetzel, et al., are based on two sheets of conductive glass sealed with organic adhesive at the edges (the conductive glass projects beyond the adhesive on each side, allowing for current takeoff). These cells operate at a voltage of about 700 mV and a current density of 15 mA/sq. cm under peak solar illumination, with the counter-electrode being the positive pole.

Efforts have been made to increase the active area and breadth of cells by laying down parallel conducting strips on a conducting glass surface, thereby enabling a large-area, broad-cell construction. U.S. Patent Application Publication No. 20050072458 to Goldstein discloses a large-area, broad conductive glass or conductive plastic for a dye cell. In one embodiment, the parallel conductors are inert strips or wires of titanium, molybdenum, tungsten, chromium or their alloys bonded directly to the conducting surface of the glass by means of an inert, electrically conducting ceramic adhesive. Broad, large area cells of 10-15 cm per side with adequate current takeoff and improved performance are thus enabled.

To date, there has been no real commercialization of photovoltaic dye cells, despite the great techno-economic potential thereof. It would be highly advantageous to have, a large-area photovoltaic dye cell that is characterized by low ohmic resistance, is low-cost and robust, and successfully addresses the various shortcomings of the prior art.

### SUMMARY OF THE INVENTION

According to the teachings of the present invention there is provided a photovoltaic cell for converting a light source into electricity, including: (a) a housing adapted to enclose the cell, including an at least partially transparent cell wall having an interior surface; (b) an electrolyte, disposed within the cell wall, containing a redox species; (c) an at least partially transparent conductive coating disposed on the interior surface; (d) an anode including: (i) a porous titania film disposed on the conductive coating, and adapted to make intimate contact with the redox species, the film having a plurality of continuous areas separated by gaps disposed along a length of the film, and (ii) a dye, absorbed on a surface of the porous film, the dye and the film adapted to convert photons to electrons; (e) a cathode disposed within the housing, substantially opposite the anode, to effect electrolytic communication, via the electrolyte, with the porous film, and (f) at least two conductor structures, disposed within the gaps, electrically connected to the anode and to the conductive coating, and abutting the porous film, each conductor structure including an electrically conductive structural element, at least partially surrounded by an electrically conductive ceramic layer, each structure forming a protrusion protruding above the (cathode-facing) surface of the porous film by at least 50 micrometers, wherein, over an entire width of the porous film disposed between the conductor structures, a thickness of the porous film is within 15 micrometers and/or 50% of a nominal thickness of the film.

According to yet another aspect of the present invention there is provided a method of producing a photovoltaic cell for converting a light source into electricity, including: (a) providing a structure including: (i) a housing adapted to enclose the photovoltaic cell, and including an at least partially transparent cell wall, the cell wall having an interior surface; (ii) an at least partially transparent conductive coating disposed on the interior surface of the cell wall, within the photovoltaic cell; (iii) an anode disposed on the conductive coating, the anode including a discontinuous porous titania film, having at least first and second continuous areas separated by a gap having an average width of at least 100 micrometers; (b) subsequently inserting an electrically conductive structural element having a small dimension of at least 50 micrometers along and within the gap, between the continuous areas; (c) introducing an electrically conductive adhesive to at least partially envelop the structural element, and to electrically bridge between the structural element and the gap, the structural element and the electrically conductive adhesive forming at least a part of an uncured conductor structure, and (d) treating the uncured conductor structure to produce a first cured conductor structure within the anode of the cell.

According to further features in the described preferred embodiments, in areas within 1 mm of the conductor structures, the thickness of the porous film is within 30%, and more preferably within 20%, of the nominal thickness of the porous film.

According to still further features in the described preferred embodiments, in areas within 1 mm of the conductor structures, the thickness of the porous film is within 10 micrometers, and more preferably within about 5 micrometers, of the nominal thickness of the porous film.

According to still further features in the described preferred embodiments, over an entire width of the porous film disposed between the conductor structures, the thickness of the porous film is within 50%, preferably within 30%, and more preferably within 20%, of the nominal thickness of the porous film.

According to still further features in the described preferred embodiments, over an entire width of the porous film disposed between the conductor structures, the thickness of the porous film is within 15 micrometers, preferably within 10 micrometers, more preferably within about 5 micrometers, and most preferably within about 3 micrometers, of the nominal thickness of the porous film.

According to still further features in the described preferred embodiments, the electrically conductive structural element is selected from the group of electrically conductive structural elements consisting of a metal strip or a metal wire.

According to still further features in the described preferred embodiments, the electrically conductive structural element has a specific electrical resistivity below 1200×10⁻⁶ ohm cm, preferably below 500×10⁻⁶ ohm cm, more preferably below 200×10⁻⁶ ohm cm, and most preferably, below 50×10⁻⁶ ohm cm.

According to still further features in the described preferred embodiments, the anode and the cathode are disposed in a monolithic arrangement.

According to still further features in the described preferred embodiments, the conductive ceramic layer is covered by a solid, electrically insulating layer having a specific electrical resistivity of at least 10⁶ ohm cm.

According to still further features in the described preferred embodiments, each of the conductor structures forming the protrusion protruding above the dye impregnated, cathode-facing surface of the porous film by at least 75 micrometers, 100 micrometers, 150 micrometers, or 200 micrometers.

According to still further features in the described preferred embodiments, the redox species includes an iodine-based redox species, and the transparent conductive coating includes tin oxide.

According to still further features in the described preferred embodiments, the conductor structures have a width between 100 and 1200 micrometers, preferably below 1000 micrometers, and more preferably, below 700 micrometers.

According to still further features in the described preferred embodiments, the cathode includes: (i) a conductive carbon layer, and (ii) a catalytic component, associated with the carbon layer and adapted to catalyze a redox reaction of the redox species, the conductive carbon layer adapted to transfer electrons from the catalytic component to a current collection component of the cathode.

According to still further features in the described preferred embodiments, the conductive ceramic layer has a specific electrical resistivity below 1.0 ohm cm, preferably below 0.1 ohm cm, and yet more preferably, below 0.01 ohm cm.

According to still further features in the described preferred embodiments, the cathode directly contacts the porous titania film.

According to still further features in the described preferred embodiments, the cell further includes an insulating spacer layer, disposed between the porous titania film and the cathode.

According to still further features in the described preferred embodiments, the second continuous area is separated from a third continuous area of the porous film by a second gap having a second cured conductor structure.

According to still further features in the described preferred embodiments, the second continuous area of the porous film is bounded by the first and second cured conductor structures, and wherein over an entire width of the second area between the cured conductor structures, a thickness of the second area is within 50%, preferably within 30%, and more preferably within 20%, of a nominal thickness of the second area.

According to still further features in the described preferred embodiments, the method further includes disposing a cathode within the housing, substantially opposite the anode.

According to still further features in the described preferred embodiments, the method further includes the step of contacting a surface of the porous film with a dye, the dye and the film adapted to convert photons to electrons.

According to still further features in the described preferred embodiments, the method further includes the step of introducing an electrolyte containing a redox species within the cell wall to effect electrolytic communication, via the electrolyte, between the porous film and the cathode.

According to still further features in the described preferred embodiments, the electrically conductive adhesive, after the treating, has a specific electrical resistivity below 1.0 ohm cm, preferably below 0.1 ohm cm, and more preferably below 0.01 ohm cm.

According to still further features in the described preferred embodiments, the electrically conductive adhesive includes a ceramic material.

According to still further features in the described preferred embodiments, the electrically conductive adhesive includes an electrically conductive material selected from the group of materials consisting of titanium nitride, zirconium nitride, and titanium boride.

According to still further features in the described preferred embodiments, the electrically conductive adhesive includes tungsten particles.

According to yet another aspect of the present invention there is provided a photovoltaic cell for converting a light source into electricity, the photovoltaic cell produced by any of the methods described herein.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice. Throughout the drawings, like-referenced characters are used to designate like elements.

In the drawings:

FIG. 1 is an exemplary, schematic, cross-sectional side view of a large-area monolithic single cell that might be fabricated based on the prior art;

FIG. 2 is a schematic top view of the cell of FIG. 1, showing printed areas in long strip form, wherein adjacent printed areas are separated by conductor structures;

FIG. 3 provides an exemplary, schematic cross-sectional side view of a portion of the inventive structure, in which separate strips of a titania layer and insulating spacer layer are disposed on a glass substrate, so as to leave a gap between the strips, and

FIG. 4 is an exemplary schematic cross-sectional side view of one embodiment of a photovoltaic dye cell of the present invention.

### DESCRIPTION OF THE PREFERRED EMBODIMENTS

One aspect of the present invention is an improved monolithic structure for large-area, broad, single dye cells. In a monolithic dye cell design, generally there is a single sheet of conducting glass required per cell, with accompanying cost savings. Onto that single sheet of conducting glass are printed sequentially a porous titania photoanode layer, a porous insulating spacer layer and then a porous carbon cathode (counter-electrode) layer. After dye staining of the titania and electrolyte addition, the cell may be sealed using an outer sheet of glass, polymer, metal foil or laminate. Since the spacer layer between the titania and cathode layers can be very thin, of the order of several micrometers only, this ensures a low electrolyte resistance and hence, a lower ohmic resistance of the cell. The result is a much lower cell resistance relative to cells in which the cathode element is a separate structure, wherein such a close spacing between photoanode and cathode may be extremely difficult to achieve. The fact that the cell active layers are built up on the same support also avoids interelectrode spacing variations resulting from thermal cycling of the cell, which can be a performance limiting problem in cells having a separate cathode. Large area monolithic single cells according to the present invention have, additionally, a higher fraction of cell footprint that is optically active, relative to the monolithic multi-cell design of Kay from U.S. Pat. No. 6,069,313. Thus, the inactive opaque seal areas and conductor areas are proportionally reduced for large area single cells, and the active titania area can approach more completely the carbon cathode area in the design of the present invention. Both of these factors positively impact the cell efficiency.

FIG. 1 provides a schematic, exemplary view of a large area monolithic single cell 100 that might be fabricated based on the prior art (elements not drawn to scale). Onto a glass sheet 1 having a conductive surface layer 4 based on tin oxide, a set of evenly spaced parallel conductor structures 8 is laid down prior to the printing of the titania layers. Conductor structures 8 jut above conductive surface layer 4. In the embodiment shown, each conductor structure 8 includes a substantially chemically inert metal wire 12 bonded in place on conductive surface layer 4 by a substantially chemically inert, electrically conductive binder 16, and covered with an electrically insulating layer 20 that prevents electrical shorting-out of the conductor structures to subsequently applied layers.

By way of example, adjacent conductor structures 15 cm long and spaced 1 cm apart preferably have an ohmic drop of less than 0.5 ohms to achieve adequate dye cell current collection on a tin oxide glass having a surface resistance of 10 ohm/sq.

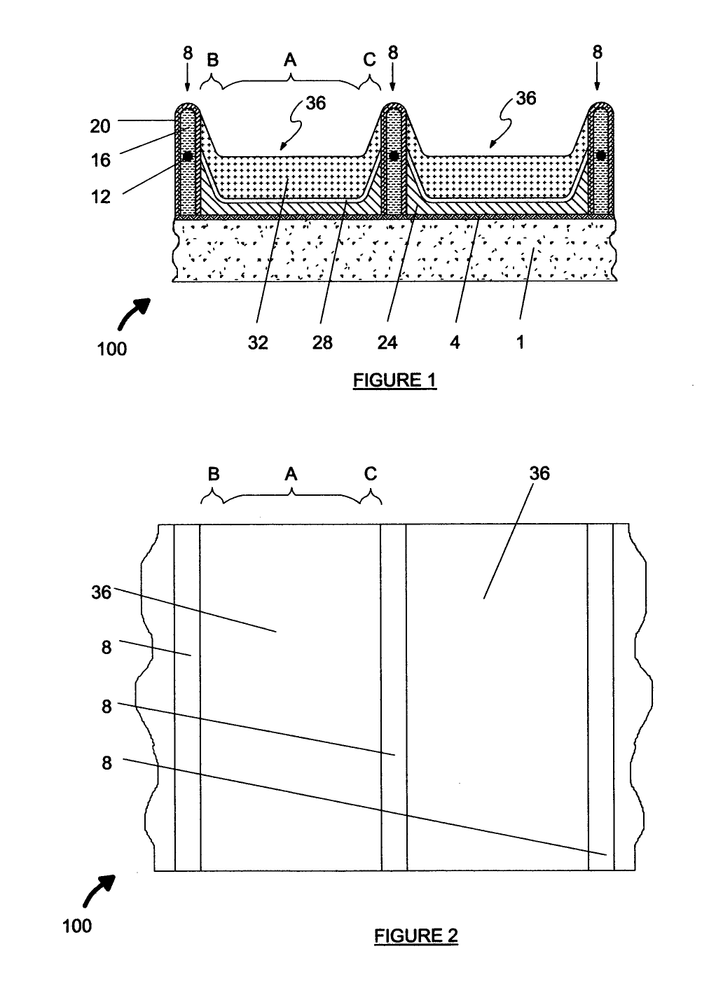

In a monolithic cell build, the critical cell components, which preferably include a titania photoanode layer 24, an insulating spacer layer 28 and a carbon counter-electrode layer 32, are typically built up, layer by layer, on glass substrate 1, by successive printing operations, including drying and sintering of these layers, to form substantially continuous printed areas 36. FIG. 2 is a schematic top view of cell 100 showing continuous printed areas 36 in long strip form, wherein adjacent printed areas 36 are separated by conductor structures 8.

When such printings are attempted by screen-printing from the appropriate pastes, there is inevitably a lack of uniformity in the layer thicknesses following sintering, due to the presence of the upraised features of conductor structures 8 on the glass surface. Conductor structures 8 may protrude well above the surface of conductive surface layer 4. The titania and spacer layers are less prominent, for example only 15 and 10 micrometers thick, respectively, following sintering. Even a conductor structure having a height of only several tens of micrometers can spoil the printing uniformity of the critical titania layer, however. Due to projecting conductor structures 8, the mesh or screen via which the paste is applied cannot be made to lie flat on the glass surface. A flat disposition on the glass surface is the optimum orientation for correct dispensing of the paste by, for example, squeegee pressure.

Consequently, after drying and sintering have been performed, a significant portion of the photoactive area of the cell is not fully parallel to the support glass. As shown in FIG. 1, in the central area of each strip, for example, area A between adjacent conductors 8, the layers are optimally thin, uniform and parallel to the substrate surface, but at areas B and C proximately-disposed to adjacent conductor structures 8, the layers (e.g., titania photoanode layer 24) are much thicker and not fully parallel to the support glass. In a typical printing, titania layer 24 of area A is 15 ±2 micrometers thick following sintering. However, we have found that titania layer 24 of areas B and C may have a maximum thickness of 30-200 micrometers or more. The main outcome of this lack of homogeneity in the thickness of the (typically screenprinted) layers is reduced cell performance. The areas close to conductor structures 8 are effectively inactive, since they may have a considerably longer ionic path characterized by higher electrolyte resistance, a longer recombination-prone ion diffusion route and reduced light transmittance, due to the excessive thickness of titania layer 24. In typical printings, where the printed strip width between the conductor structures is about 8 mm, the inactive width can be 1 mm (or more) on each side of the conductor structures, such that the cell performance loss compared with the case of uniform printing of strips across the width can approach 20%.

A similar result may be obtained using other methods of application of conductor structures in large area cells, for example, bonding of wires into grooves on the substrate or electroplating of conducting metal or metal alloy strips onto the substrate, since here as well, the conductor structures may be situated well above the surface of the substrate.

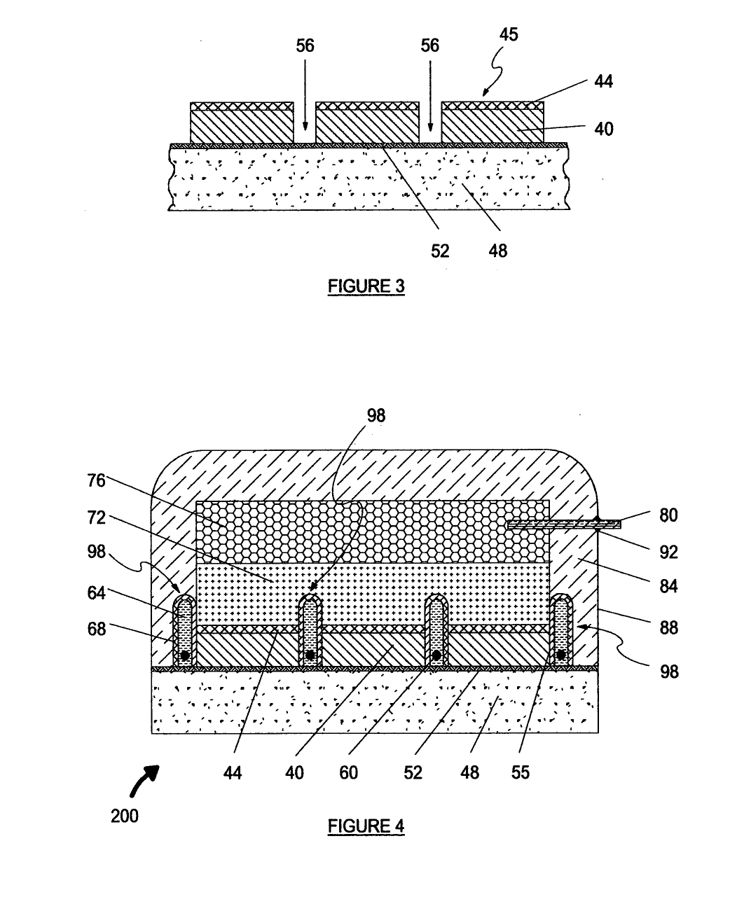

In the present invention, a strategy for uniform printing of the active layers is adopted by which the active layer printings are made prior to the application of the conductor structures. FIG. 3 provides an exemplary, schematic cross-sectional side view of a portion of an inventive structure, in which separate strips 45 of a titania layer 40 and insulating spacer layer 44 are disposed (e.g., by screenprinting) on a glass substrate 48 having a conducting tin oxide layer 52, leaving at least one gap 56 between strips 45 that may subsequently be at least partially filled by conductor structures. In this case, there is no problem in obtaining active layers having a substantially uniform or homogeneous thickness, even in the areas adjacent to such conductor structures.

Gaps 56 are preferably substantially parallel to one another.

An exemplary schematic cross-sectional side view of one embodiment of a monolithic cell 200 of the present invention is provided in FIG. 4. Highly electrically conductive structural elements or cores such as wires 60 are positioned in the gaps (such as gaps 56 shown in FIG. 3) between the layers and/or printings (e.g., titania layer 40 and optional insulating spacer layer 44), or adjacent to a termination or end 55 of the printings. Preferably, sufficient tension is applied to wires 60 to ensure close and substantially parallel placement thereof to the tin oxide surface. This placement procedure may be performed using a jig or other means known in the art.

Wires 60 are then permanently bonded in place by an electrically conducting adhesive layer (e.g., containing a ceramic adhesive), which may be added by a dosing dispenser, to produce uncured conductor structures. These uncured conductor structures may undergo treatment (e.g., a heat treatment) to produce a cured or at least partially sintered conductor structure such as conductor structures 98. Conductor structures 98 may include highly electrically conductive structural elements such as wires 60, at least partially surrounded by, and preferably completely surrounded by, an electrically conducting binder layer such as electrically conductive ceramic or binder layer 64 formed by the treating of the electrically conducting adhesive layer. Binder layer 64 may contain a ceramic material and one or more electrically conductive materials such as tungsten, titanium nitride, zirconium nitride, and titanium boride.

Conductor structures 98 may also have an electrically insulating layer such as an insulating ceramic layer 68, which at least partially and preferably completely envelops or surrounds wire 60 and electrically conducting binder layer 64.

In the photovoltaic cell and method of the present invention, depending on which conductor application method is employed, the conductor structures may be between 0.1 mm and 2 mm wide, may be spaced about 5-20 mm apart on the conducting glass, and may be at least 50 micrometers to 200 micrometers high (or more) above the surface of the conducting glass. Preferably, the conductor structures may have a width of less than 1 mm, and more preferably, less than 0.7 mm.

A cathode layer such as porous carbon-based cathode 72, optionally catalyzed, may be screenprinted or laid directly on top of insulating spacer layer 44. Alternatively, porous carbon-based cathode 72 may be screenprinted or laid directly upon titania layer 40.

Current takeoff from the cathode may be achieved by various means, for example by bonding to carbon-based cathode 72, a sheet of graphite foil 76 carrying an embedded metal mesh or strip tab 80, and the layers beneath may be kept well compressed following sealing by additional inclusion of an optional sponge element (not shown).

Titania layer 40 may be coated by a dye using a dye solution printed onto porous carbon-based cathode 72, which enables the dye to percolate through to titania layer 40, where it chemisorbs strongly. Following evaporation off of the dye solvent, the cell electrolyte is added to the cell by printing onto porous cathode 72. In the exemplary embodiment provided in FIG. 4, cell 200 is substantially closed off and sealed at the edges using a sealant layer such as polymer sealant layer 84 backed by a housing such as a metal foil 88 (for a lightweight design), in which case, a metal tab 80 may be brought through foil 88 via an insulating grommet 92 that may be attached to foil 88. More standard closures, such as a glass sheet sealed at the edges with polymer or adhesive, may also be feasible. Current takeoff from the wire-based structures of the photoanode or the embedded tab of the cathode, which pass out of the inside of the cell via the sealed edges of the cell, may be effected by welded metal strips that can make connection to the adjacent cell in a modular assembly of cells (not shown).

Thus, in the cell of the present invention, the active layers may have a substantially uniform or homogeneous thickness, even including the areas adjacent to the conductor structures. Along the entire width of the strips disposed between the conductor structures, and adjacent (within 1 mm) to conductor structures 98 in particular, the thickness of a strip of strips 45 is within 50%, preferably within 30%, and more preferably within about 20%, of the nominal thickness of the strip. Similarly, with regard to each of the individual components of strips 45, such as titania layer 40 and insulating spacer layer 44, the thickness of a particular component is within 50%, preferably within 30%, and more preferably, within about 20%, of the nominal thickness of the strip along the entire width of the strips disposed between the conductor structures, and in particular, in the areas adjacent (within 1 mm) to conductor structures 98.

By way of example, in a dye cell of the present invention, and given a titania layer 40 screenprinted onto a substrate and having a nominal thickness of 15 micrometers, strip 40 would have a thickness of no more than 22.5 micrometers along the entire width of the strip, including the areas adjacent to the conductor structures. Preferably, strip 40 would have a thickness of no more than 19.5 micrometers along the entire width of the strip, and more preferably, no more than about 18 micrometers.

Typical printing accuracy of a layer (such as a titania layer) onto flat glass may be about +/−2 micrometers.

As used herein in the specification and in the claims section that follows, the term “nominal thickness”, with respect to a strip such as strip 45, a component of the strip, or a porous layer such as a titania layer, refers to an average thickness, within a substantially flat area A, of the strip, component, or layer, respectively, that is situated at least 2.5 mm from any of the conductor structures.

In absolute terms, along the entire width of the strips disposed between the conductor structures, and adjacent (within 1 mm) to conductor structures 98 in particular, the thickness of a strip of strips 45 is within 15 micrometers, preferably within 10 micrometers, and more preferably within about 5 micrometers, of the nominal thickness of the strip. Similarly, with regard to each of the individual components of strips 45, such as titania layer 40 and insulating spacer layer 44, the thickness of a particular component is within 15 micrometers, preferably within 10 micrometers, and more preferably within about 5 micrometers, of the nominal thickness of the strip along the entire width of the strips disposed between the conductor structures, and in particular, in the areas adjacent (within 1 mm) to conductor structures 98.

By way of example, in a dye cell of the present invention, and given a titania layer 40 screenprinted onto a substrate and having a nominal thickness of 10 micrometers, strip 40 would have a thickness of no more than 25 micrometers along the entire width of the strip, including the areas adjacent to the conductor structures. Preferably, strip 40 would have a thickness of no more than 20 micrometers along the entire width of the strip, and more preferably, no more than about 15 micrometers.

The invention is not limited to the exemplary sequence of operations provided hereinabove, and various modifications will be apparent to those of ordinary skill in the art. For example, the active layers may be printed on the substrate in one large area printing without any separations and the gaps cleared in a subsequent ablation step. Similarly, it is possible to print the carbon layers on the spacer layers prior to the laying down of conductor structures. The sequence may also be adjusted in order to enable proper coordination of drying and sintering steps in cell preparation, or in order to better accommodate the placing of conductors in grooves on the substrate surface or plated onto it. Removable masking layers may also be laid down in order to prevent contamination of prior placed active layers or electrical shorting of subsequent layers.

As used herein, the term “monolithic” and the like, with regard to a dye cell, refers to a dye cell structure in which both the photoanode and the cathode layers of the cell are supported by a common conducting glass support. The term “monolithic” and the like, is specifically meant to exclude dye cell structures in which the photoanode is supported by a first glass support and the cathode is supported by a second glass support, such that the photoanode and the cathode are substantially disposed therebetween. Typically, monolithic dye cell structures are produced in a screenprinting process, and have a porous insulating spacer layer disposed between the photoanode and cathode layers.

Below we provide a list of various materials that may be used in photovoltaic dye cells, along with their specific electrical resistivities (in units of ohm cm), as available in the literature.

Specific Electrical Resistivities (ohm cm)

| | |
|---|---|
| Silver | 1.5 × 10⁻⁶ |
| Copper | 1.5 × 10⁻⁶ |
| Nickel | 6.2 × 10⁻⁶ |
| Platinum | 9.6 × 10⁻⁶ |
| Aluminum | 2.4 × 10⁻⁶ |
| Titanium | 39 × 10⁻⁶ |
| Bismuth | 107 × 10⁻⁶ |
| Titanium Clad Copper | ~3 × 10⁻⁶ |
| Molybdenum | 4.9 × 10⁻⁶ |
| Chromium | 11.8 × 10⁻⁶ |
| Tantalum | 12.2 × 10⁻⁶ |
| Tungsten | 4.8 × 10⁻⁶ |
| Carbon | 3000 × 10⁻⁶ |
| Graphite | 1000 × 10⁻⁶ |
| Titanium nitride | 25 × 10⁻⁶ |
| Tin oxide | 500 × 10⁻⁶ |
| Titanium dioxide | ~10¹² |
| Alumina binder | ~10¹⁴ |
| Sensitizer dye | ~10⁹ |

Conductivity is inversely related to the resistivity. It is evident from these values that metals such as silver, copper, aluminum, tungsten are intrinsically highly conducting, while other metals such as titanium, and some conducting fillers such as titanium nitride are somewhat less conducting. Carbon, graphite, and tin oxide are much poorer conductors. Materials such as titanium dioxide, alumina binder and sensitizer dyes, are properly classed as insulators, having resistivities that are at least 13 orders of magnitude higher than materials that are considered to be genuine conductors.

Not only is the specific resistivity of a material important in determining the resistance of a layer of the material, but also the layer thickness, its length and width, and the continuity of the layer components is crucial. Thus, in dye cells, the conductive tin oxide layer on the glass is an exceedingly poor conductor, not just because its specific resistivity is much higher than the specific resistivity of metals, but also because the layer has to be extremely thin (typically 0.5 micrometers) in order for the layer to remain transparent and for light to be able to enter the cell with adequate transmittance. Consequently, the conductive tin oxide layer on the glass is a poor vehicle for conveying current out of the cell along the broad plane of the tin oxide layer.

Conductor structures 98, such as metal wires bonded in place on a tin oxide glass by an electrically conductive ceramic adhesive, may be beneficial as current takeoff elements on the basis of their intrinsic conductivity. However, other criteria for the structures include low contact resistance to the tin oxide surface and minimal shading of light to the cell. By way of example, we can consider a dye cell having a square geometry of 15 cm per side, which may generate, at 7% conversion efficiency, a peak current of about 3 amperes. Parallel conductor structures disposed across the face of the device, each of length 15 cm, width 1 mm and spaced 1 cm apart, yield an acceptably low shading of 10%. For adequate current takeoff on tin oxide glass having a surface resistance of 10 ohm/sq., however, the resistance between adjacent conductor structures should preferably not exceed about 0.5 ohms.

Generally speaking, the highly electrically conductive structural elements such as wires 60, disposed within conductor structures 98, have specific electrical resistivities of less than 1200×10⁻⁶ ohm cm, preferably below 500×10⁻⁶ ohm cm, more preferably, below 200×10⁻⁶ ohm cm, yet more preferably, less than 100×10⁻⁶ ohm cm, and most preferably, below 50×10⁻⁶ ohm cm.

With regard to the cured layer produced from conducting adhesive paste or layer 64, the specific electrical resistivity is less than 1.0 ohm cm, preferably, less than 0.1 ohm cm, more preferably, less than 0.05 ohm cm, and most preferably, less than 0.01. Some materials suitable for use in, or with, conducting adhesive layer 64 may have specific electrical resistivities that are several orders of magnitude lower.

With regard to the electrically insulating layer (such as ceramic layer 68) that generally envelops the electrically conductive structural element and the conducting ceramic layer, and with regard to insulating spacer layer 44 as well, the specific electrical resistivity is generally at least 10⁶ ohm cm, preferably, at least 10⁸ ohm cm, and more typically, at least 10¹⁰-10¹⁴ ohm cm.

Although the invention has been described in conjunction with specific embodiments thereof, it is evident that many alternatives, modifications and variations will be apparent those skilled in the art. Accordingly, it is intended to embrace all such alternatives, modifications and variations. All publications and patents mentioned in this specification are herein incorporated in their entirety by reference into the specification, to the same extent as if each individual publication or patent was specifically and individually indicated to be incorporated herein by reference. In addition, citation or identification of any reference in this application shall not be construed as an admission that such reference is available as prior art to the present invention.

1-31. (canceled)

32. A photovoltaic cell for converting a light source into electricity, the cell comprising:
(a) a housing adapted to enclose the photovoltaic cell, said housing including an at least partially transparent cell wall, said cell wall having an interior surface;
(b) an electrolyte, disposed within said cell wall, said electrolyte containing a redox species;
(c) an at least partially transparent conductive coating disposed on said interior surface of said cell wall, within the photovoltaic cell;
(d) an anode including:
(i) a porous titania film disposed on said conductive coating, and adapted to make intimate contact with said redox species, said film having a plurality of continuous areas separated by gaps in said film, and
(ii) a dye, absorbed on a surface of said porous film, said dye and said film adapted to convert photons to electrons;
(e) a cathode disposed within said housing, substantially opposite said anode, said cathode disposed in electrolytic communication, via said electrolyte, with said porous film, and
(f) at least two conductor structures, disposed within said gaps, electrically connected to said anode and to said conductive coating, and abutting said porous film, each conductor structure of said structures including an electrically conductive structural element, at least partially surrounded by an electrically conductive ceramic layer, each said structure forming a protrusion protruding above said surface of said porous film by at least 50 micrometers,
said anode having at least one of the following structural features:
over an entire width of said porous film disposed between said conductor structures, a thickness of said porous film is within 50%, preferably within 30%, and more preferably within 20%, of a nominal thickness of said porous film, and
over an entire width of said porous film disposed between said conductor structures, a thickness of said porous film is within 15 micrometers, preferably within 10 micrometers, and more preferably within about 5 micrometers, of said nominal thickness of said porous film.

33. The cell of claim 32, wherein in areas within 1 mm of said conductor structures, said thickness of said porous film is within 30%, and more preferably within 20%, of said nominal thickness of said porous film.

34. The cell of claim 32, wherein in areas within 1 mm of said conductor structures, said thickness of said porous film is within 10 micrometers, and more preferably within about 5 micrometers, of said nominal thickness of said porous film.

35. The cell of claim 32, wherein over an entire width of said porous film disposed between said conductor structures, said thickness of said porous film is within 50%, preferably within 30%, and more preferably within 20%, of said nominal thickness of said porous film.

36. The cell of claim 32, wherein over an entire width of said porous film disposed between said conductor structures, said thickness of said porous film is within 15 micrometers, preferably within 10 micrometers, and more preferably within about 5 micrometers, of said nominal thickness of said porous film.

37. The cell of claim 32, wherein said electrically conductive structural element is selected from the group of electrically conductive structural elements consisting of a metal strip or a metal wire.

38. The cell of claim 32, wherein said electrically conductive structural element has a specific electrical resistivity below 1200×10⁻⁶ ohm cm, preferably below 500×10⁻⁶ ohm cm, more preferably below 200×10⁻⁶ ohm cm, and most preferably, below 50×10⁻⁶ ohm cm.

39. The cell of claim 32, wherein said anode and said cathode are disposed in a monolithic arrangement.

40. The cell of claim 32, wherein said conductive ceramic layer is covered by a solid, electrically insulating layer having a specific electrical resistivity of at least 10⁶ ohm cm.

41. The cell of claim 32, each of said conductor structures forming said protrusion protruding above said surface of said porous film by at least 75 micrometers, 100 micrometers, 150 micrometers, or 200 micrometers.

42. The cell of claim 32, wherein said redox species includes an iodine-based redox species, and said transparent conductive coating includes tin oxide.

43. The cell of claim 32, wherein said conductor structures have a width between 100 and 1200 micrometers.

44. The cell of claim 32, said cathode including:
(i) a conductive carbon layer, and
(ii) a catalytic component, associated with said carbon layer and adapted to catalyze a redox reaction of said redox species,
said conductive carbon layer adapted to transfer electrons from said catalytic component to a current collection component of said cathode.

45. The cell of claim 32, wherein said conductive ceramic layer has a specific electrical resistivity below 1.0 ohm cm, preferably below 0.1 ohm cm, and yet more preferably, below 0.01 ohm cm.

46. The cell of claim 32, wherein said cathode directly contacts said porous titania film.

47. The cell of claim 32, further comprising an insulating spacer layer, disposed between said porous titania film and said cathode.

48. A method of producing a photovoltaic cell for converting a light source into electricity, the method comprising the steps of:
(a) providing a structure including:
(i) a housing adapted to enclose the photovoltaic cell, and including an at least partially transparent cell wall, said cell wall having an interior surface;
(ii) an at least partially transparent conductive coating disposed on said interior surface of said cell wall, within the photovoltaic cell;
(iii) an anode disposed on said conductive coating, said anode including a porous titania film,
wherein said porous film is a discontinuous film having at least a first continuous area and a second continuous area separated by a gap having an average width of at least 100 micrometers;
(b) subsequently inserting an electrically conductive structural element along and within said gap, between said continuous areas, said structural element having a small dimension of at least 50 micrometers;
(c) introducing an electrically conductive adhesive to at least partially envelop said structural element, and to electrically bridge between said structural element and said gap, said structural element and said electrically conductive adhesive forming at least a part of an uncured conductor structure, and
(d) treating said uncured conductor structure to produce a first cured conductor structure within said anode of the photovoltaic cell.

49. The method of claim 48, further comprising the step of disposing a cathode within said housing, substantially opposite said anode.

50. The method of claim 48, further comprising the step of contacting a surface of said porous film with a dye, said dye and said film adapted to convert photons to electrons.

51. The method of claim 48, further comprising the step of introducing an electrolyte within said cell wall to effect electrolytic communication, via said electrolyte, between said porous film and said cathode, said electrolyte containing a redox species.
